(19) United States
(12) Patent Application Publication
(10) Pub. No.: US 2022/0115627 A1
(43) Pub. Date: Apr. 14, 2022

(54) ENCAPSULATION LAYER AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Liying PENG, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/771,474

(22) PCT Filed: Apr. 14, 2020
(86) PCT No.: PCT/CN2020/084606

§ 371 Date: Jun. 10, 2020

(30) Foreign Application Priority Data
Mar. 31, 2020 (CN) 202010246391.0

(51) Int. Cl. H01L 51/52; H01L 51/56

(52) U.S. Cl. CPC H01L 51/5256; H01L 51/56; H01L 51/5246

(57) ABSTRACT

An encapsulation layer and a manufacturing method thereof are provided. The encapsulation layer includes a first inorganic layer, an adhesive layer, an organic layer, and a second inorganic layer. The adhesive layer is disposed on the first inorganic layer, a surface of the adhesive layer away from the first inorganic layer has a microporous structure, the organic layer is disposed on the adhesive layer and filled in the microporous structure, and the second inorganic layer covers the organic layer.

### FIELD OF INVENTION

The present disclosure relates to the field of panel technologies, and more particularly, to an encapsulation layer and a manufacturing method thereof.

### BACKGROUND OF INVENTION

At present, encapsulation layers of flexible OLED panels become more and more thinner. Current encapsulation layer is mainly an inorganic-organic stacked structure. However, an organic layer is often thicker, which is not beneficial for later screen bending, and adhesion between the organic layer and an inorganic layer is weaker, which reduces encapsulation effect of the encapsulation layers.

Technical problem: the present disclosure provides an encapsulation layer and a manufacturing method thereof to solve a problem of weaker adhesion between an organic layer and an inorganic layer and improve the encapsulation effect.

### SUMMARY OF INVENTION

An embodiment of the present disclosure provides an encapsulation layer, which comprises:

a first inorganic layer, wherein a material of the first inorganic layer comprises one or more of SiNx, SiON, or Al₂O₃;

an adhesive layer disposed on the first inorganic layer, wherein a surface of the adhesive layer away from the first inorganic layer has a microporous structure;

an organic layer disposed on the adhesive layer and filled in the microporous structure; and

a second inorganic layer covering the organic layer.

In the encapsulation layer provided by the present disclosure, a material of the adhesive layer comprises SiNx and SiON.

In the encapsulation layer provided by the present disclosure, a pore size of the microporous structure ranges from 1 nm to 30 nm.

In the encapsulation layer provided by the present disclosure, a thickness of the adhesive layer ranges from 0.5 μm to 1 μm.

In the encapsulation layer provided by the present disclosure, a thickness of the first inorganic layer and a thickness of the second inorganic layer both range from 0.5 μm to 1 μm.

In the encapsulation layer provided by the present disclosure, a thickness of the microporous structure accounts for 5% to 15% of a total thickness of the adhesive layer.

An embodiment of the present disclosure further provides an encapsulation layer which comprises:

a first inorganic layer;

an adhesive layer disposed on the first inorganic layer, wherein a surface of the adhesive layer away from the first inorganic layer has a microporous structure;

an organic layer disposed on the adhesive layer and filled in the microporous structure; and

a second inorganic layer covering the organic layer.

In the encapsulation layer provided by the present disclosure, a material of the adhesive layer comprises SiNx and SiON.

In the encapsulation layer provided by the present disclosure, a pore size of the microporous structure ranges from 1 nm to 30 nm.

In the encapsulation layer provided by the present disclosure, a thickness of the adhesive layer ranges from 0.5 μm to 1 μm.

In the encapsulation layer provided by the present disclosure, a thickness of the first inorganic layer and a thickness of the second inorganic layer both range from 0.5 μm to 1 μm.

In the encapsulation layer provided by the present disclosure, a thickness of the microporous structure accounts for 5% to 15% of a total thickness of the adhesive layer.

An embodiment of the present disclosure further provides a manufacturing method of an encapsulation layer. The method comprises:

providing a first inorganic layer;

forming an adhesive layer on the first inorganic layer, wherein a surface of the adhesive layer away from the first inorganic layer has a microporous structure;

forming an organic layer on the adhesive layer, wherein the organic layer is disposed on the adhesive layer and filled in the microporous structure; and

forming a second inorganic layer on the organic layer.

In the manufacturing method of the encapsulation layer provided by the present disclosure, the step of forming the adhesive layer on the first inorganic layer, wherein the surface of the adhesive layer away from the first inorganic layer has the microporous structure, comprises:

passing a deposited gas into a reaction chamber, wherein the deposited gas is deposited on the first inorganic layer to form a base of the adhesive layer; and

passing the deposited gas and an additional gas into the reaction chamber at a same time, wherein the deposited gas is deposited on the base of the adhesive layer to form the microporous structure, a molecular mass of the additional gas is greater than a molecular mass of the deposited gas, and the additional gas does not react with the deposited gas.

In the manufacturing method of the encapsulation layer provided by the present disclosure, the additional gas is one or more of a gas having a molecular mass greater than that of silane gas, argon gas, krypton gas, or radon gas.

In the manufacturing method of the encapsulation layer provided by the present disclosure, the step of forming the adhesive layer on the first inorganic layer, wherein the surface of the adhesive layer away from the first inorganic layer has the microporous structure, comprises:

passing a deposited gas into a reaction chamber, wherein the deposited gas is deposited on the first inorganic layer to form a prefabricated adhesive layer; and

performing etching on a surface of the prefabricated adhesive layer using an etching gas to form the adhesive layer with the surface having the microporous structure.

Beneficial effect: the present disclosure provides an encapsulation layer and a manufacturing method thereof. The encapsulation layer includes a first inorganic layer, an adhesive layer, an organic layer, and a second inorganic layer. The adhesive layer is disposed on the first inorganic layer, a surface of the adhesive layer away from the first inorganic layer has a microporous structure, the organic layer is disposed on the adhesive layer and filled in the microporous structure, and the second inorganic layer covers the organic layer. The adhesive layer is disposed on the first inorganic layer, and an upper surface of the adhesive layer away from the first inorganic layer has the microporous structure, which makes the organic layer leveled, reduces a thickness of the organic layer, and improves adhesion between the first inorganic layer and the organic layer, thereby improving encapsulation effect.

### DESCRIPTION OF DRAWINGS

The accompanying figures to be used in the description of embodiments of the present disclosure will be described in brief to more clearly illustrate the technical solutions of the embodiments. The accompanying figures described below are only part of the embodiments of the present disclosure, from which those skilled in the art can derive further figures without making any inventive efforts.

FIG. 1 is a schematic cross-sectional structural diagram of an encapsulation layer according to an embodiment of the present disclosure.

FIG. 2 is a schematic cross-sectional structural diagram of a display panel according to an embodiment of the present disclosure.

FIG. 3 is a flowchart of a manufacturing method of an encapsulation layer according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all embodiments. Based on the embodiments in the present disclosure, all other embodiments obtained by those skilled in the art without creative efforts are within the scope of the present disclosure.

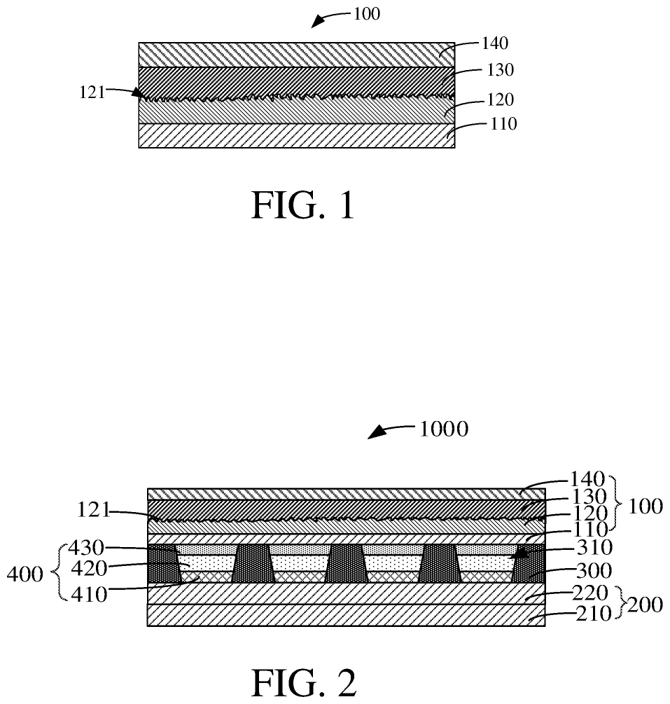

Referring to FIG. 1, FIG. 1 is a schematic cross-sectional structural diagram of an encapsulation layer according to an embodiment of the present disclosure. The present disclosure provides an encapsulation layer 100. The encapsulation layer 100 includes a first inorganic layer 110, an adhesive layer 120, an organic layer 130, and a second inorganic layer 140.

A material of the first inorganic layer 110 comprises one or more of SiNx, SiON, or Al₂O₃. A thickness of the first inorganic layer 110 ranges from 0.5 μm to 1 μm. In some embodiments, the thickness of the first inorganic layer 110 may be 0.6 μm, 0.8 μm, or 0.9 μm, etc.

The adhesive layer 120 is disposed on the first inorganic layer 110. A surface of the adhesive layer 120 away from the first inorganic layer 110 has a microporous structure 121. A pore size of the microporous structure 121 ranges from 1 nm to 30 nm. In some embodiments, the pore size of the microporous structure 121 may be 5 nm, 10 nm, 13 nm, 16 nm, or 18 nm, etc. A thickness of the microporous structure 121 accounts for 5% to 15% of a total thickness of the adhesive layer 120. In some embodiments, the thickness of the microporous structure 121 may account for 7%, 10%, 12%, or 14% of the total thickness of the adhesive layer 120. A thickness of the adhesive layer 120 ranges from 0.5 μm to 1 μm. In some embodiments, the thickness of the adhesive layer 120 may be 0.6 μm, 0.8 μm, or 0.9 μm, etc. A material of the adhesive layer 120 comprises one or more of SiNx, or SiON.

The organic layer 130 is disposed on the adhesive layer 120 and is filled in the microporous structure 121. A material of the organic layer 130 includes one or more of polyvinyl alcohol, polyurethane acrylate polymer, or polyimide resin.

The second inorganic layer 140 is disposed on the organic layer 130. A material of the second inorganic layer 140 comprises one or more of SiNx, SiON, or Al₂O₃. A thickness of the second inorganic layer 140 ranges from 0.5 μm to 1 μm. In some embodiments, the thickness of the second inorganic layer 140 may be 0.6 μm, 0.8 μm, or 0.9 μm, etc.

In the present disclosure, the adhesive layer is disposed on the first inorganic layer, and an upper surface of the adhesive layer away from the first inorganic layer has the microporous structure, which is beneficial for leveling of the organic layer and reduces a thickness of the organic layer. Since the microporous structure is disposed on the adhesive layer and the organic layer is filled in the microporous structure, adhesion between the first inorganic layer and the organic layer is improved, thereby improving encapsulation effect of the encapsulation layer.

Referring to FIG. 2, FIG. 2 is a schematic cross-sectional structural diagram of a display panel according to an embodiment of the present disclosure. An embodiment of the present disclosure further provides a display panel 1000. The display panel 1000 includes an array substrate 200, a pixel definition layer 300, a light-emitting device layer 400, and an encapsulation layer 100.

The array substrate 200 includes a substrate 210 and thin film transistors 220 disposed on the substrate 210.

The pixel definition layer 300 is disposed on the array substrate 200. The pixel definition layer 300 has through-holes 310. The through-holes 310 penetrate through the pixel definition layer and expose the array substrate 200.

The light-emitting device layer 400 is disposed in the through-holes 310. The light-emitting device layer 400 includes a first electrode layer 410, a light-emitting layer 420, and a second electrode layer 430 disposed in a stack. The light-emitting layer 420 may be an organic light-emitting layer. The light-emitting layer 420 may further include at least one of a hole injection layer, a hole transport layer, a hole blocking layer, an electron transport layer, or an electron injection layer.

The encapsulation layer 100 covers the pixel definition layer 300 and the light-emitting device layer 400. The encapsulation layer 100 includes features of the encapsulation layer 100 provided by the present disclosure.

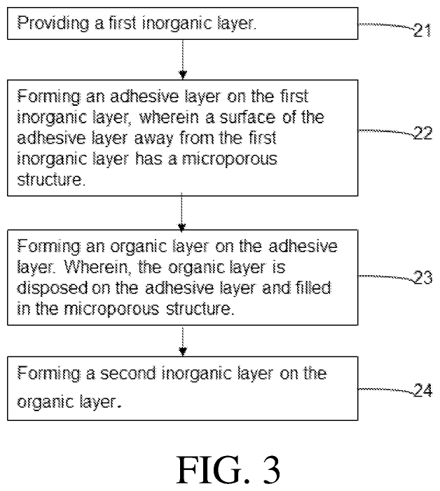

Referring to FIG. 3, FIG. 3 is a flowchart of a manufacturing method of an encapsulation layer according to an embodiment of the present disclosure. An embodiment of the present disclosure further provides a manufacturing method of an encapsulation layer 100. The method comprises following steps:

Step 21: providing a first inorganic layer 110.

A material of the first inorganic layer 110 comprises one or more of SiNx, SiON, or Al₂O₃. A thickness of the first inorganic layer 110 ranges from 0.5 μm to 1 μm. In some embodiments, the thickness of the first inorganic layer 110 may be 0.6 μm, 0.8 μm, or 0.9 μm, etc.

Step 22: forming an adhesive layer 120 on the first inorganic layer 110, wherein a surface of the adhesive layer 120 away from the first inorganic layer 110 has a microporous structure 121.

A deposited gas is passed into a reaction chamber, and the deposited gas deposits an adhesive layer material on the first inorganic layer 110 to form a base of the adhesive layer.

The deposited gas and an additional gas are passed into the reaction chamber at a same time, and at an ending period of the reaction for the deposited gas depositing on the base of the adhesive layer, since a molecular mass of the additional gas is greater than that of the deposited gas, a depositing velocity of the additional gas is greater than that of the deposited gas, and the additional gas does not react with the deposited gas. Therefore, during the process of the deposited gas forming a solid phase, molecules of the additional gas are mixed in the solid phase formed by the deposited gas, and after the reaction, the solid phase formed by the deposited gas is the microporous structure, thereby forming the adhesive layer 120 having the microporous structure 121. The molecular mass of the additional gas is greater than that of the deposited gas, and the additional gas does not react with the deposited gas. The additional gas is one or more of a gas having a molecular mass greater than that of silane gas, argon gas, krypton gas, or radon gas.

In another embodiment of the present disclosure, the deposited gas is passed into the reaction chamber, and the deposited gas is deposited on the first inorganic layer 110 to form a prefabricated adhesive layer. Then, a surface of the prefabricated adhesive layer is etched using an etching gas to form the adhesive layer 120 with a surface having the microporous structure 121.

The reaction chamber may be a reaction chamber of a physical vapor deposition equipment or a chemical vapor deposition equipment, and may also be a reactor of a magnetron sputtering equipment or a reaction chamber of a vacuum evaporation equipment.

Step 23: forming an organic layer 130 on the adhesive layer 120. Wherein, the organic layer 130 is disposed on the adhesive layer 120 and filled in the microporous structure 121.

The organic layer 130 is manufactured on the adhesive layer 120 by inkjet printing. Since the adhesive layer 120 has the microporous structure 121, the organic layer 130 can be adsorbed into the microporous structure due to adsorption characteristics of the microporous structure 121, which is beneficial for leveling of the organic layer 130 and reduces a thickness of the organic layer 130. A material of the organic layer 130 includes one or more of polyvinyl alcohol, polyurethane acrylate polymer, or polyimide resin.

Step 24: forming a second inorganic layer 140 on the organic layer 130.

The second inorganic layer 140 is formed by depositing a second inorganic layer material on the organic layer 130 using chemical vapor deposition. A material of the second inorganic layer 140 comprises one or more of SiNx, SiON, or Al₂O₃. A thickness of the second inorganic layer 140 ranges from 0.5 μm to 1 μm. In some embodiments, the thickness of the second inorganic layer 140 may be 0.6 μm, 0.8 μm, or 0.9 μm, etc.

An encapsulation layer, a manufacturing method thereof, and a display panel are provided. The encapsulation layer includes a first inorganic layer, an adhesive layer, an organic layer, and a second inorganic layer. The adhesive layer is disposed on the first inorganic layer, a surface of the adhesive layer away from the first inorganic layer has a microporous structure, the organic layer is disposed on the adhesive layer and filled in the microporous structure, and the second inorganic layer covers the organic layer. The adhesive layer is disposed on the first inorganic layer, and an upper surface of the adhesive layer away from the first inorganic layer has the microporous structure. Using adsorption characteristics of the microporous structure improves leveling effect of the organic layer, reduces a thickness of the organic layer, and improves adhesion between the first inorganic layer and the organic layer, thereby improving the encapsulation effect.

The embodiments of the present disclosure are described in detail above. Specific examples are used herein to explain the principles and implementation of the present disclosure. The descriptions of the above embodiments are only used to help understand the present disclosure. Meanwhile, for those skilled in the art, the range of specific implementation and application may be changed according to the ideas of the present disclosure. In summary, the content of the specification should not be construed as causing limitations to the present disclosure.

What is claimed is:

1. An encapsulation layer, comprising:
a first inorganic layer, wherein a material of the first inorganic layer comprises one or more of SiNx, SiON, or Al₂O₃;
an adhesive layer disposed on the first inorganic layer, wherein a surface of the adhesive layer away from the first inorganic layer has a microporous structure;
an organic layer disposed on the adhesive layer and filled in the microporous structure; and
a second inorganic layer covering the organic layer.

2. The encapsulation layer according to claim 1, wherein a material of the adhesive layer comprises SiNx and SiON.

3. The encapsulation layer according to claim 1, wherein a pore size of the microporous structure ranges from 1 nm to 30 nm.

4. The encapsulation layer according to claim 1, wherein a thickness of the adhesive layer ranges from 0.5 μm to 1 μm.

5. The encapsulation layer according to claim 1, wherein a thickness of the first inorganic layer and a thickness of the second inorganic layer both range from 0.5 μm to 1 μm.

6. The encapsulation layer according to claim 1, wherein a thickness of the microporous structure accounts for 5% to 15% of a total thickness of the adhesive layer.

7. An encapsulation layer, comprising:
a first inorganic layer;
an adhesive layer disposed on the first inorganic layer, wherein a surface of the adhesive layer away from the first inorganic layer has a microporous structure;
an organic layer disposed on the adhesive layer and filled in the microporous structure; and
a second inorganic layer covering the organic layer.

8. The encapsulation layer according to claim 7, wherein a material of the adhesive layer comprises SiNx and SiON.

9. The encapsulation layer according to claim 7, wherein a pore size of the microporous structure ranges from 1 nm to 30 nm.

10. The encapsulation layer according to claim 7, wherein a thickness of the adhesive layer ranges from 0.5 μm to 1 μm.

11. The encapsulation layer according to claim 7, wherein a thickness of the first inorganic layer and a thickness of the second inorganic layer both range from 0.5 μm to 1 μm.

12. The encapsulation layer according to claim 7, wherein a thickness of the microporous structure accounts for 5% to 15% of a total thickness of the adhesive layer.

13. A manufacturing method of an encapsulation layer, comprising following steps:
providing a first inorganic layer;
forming an adhesive layer on the first inorganic layer, wherein a surface of the adhesive layer away from the first inorganic layer has a microporous structure;
forming an organic layer on the adhesive layer, wherein the organic layer is disposed on the adhesive layer and filled in the microporous structure; and
forming a second inorganic layer on the organic layer.

14. The manufacturing method of the encapsulation layer according to claim 13, wherein the step of forming the adhesive layer on the first inorganic layer, wherein the surface of the adhesive layer away from the first inorganic layer has the microporous structure, comprises:
passing a deposited gas into a reaction chamber, wherein the deposited gas is deposited on the first inorganic layer to form a base of the adhesive layer; and
passing the deposited gas and an additional gas into the reaction chamber at a same time, wherein the deposited gas is deposited on the base of the adhesive layer to form the microporous structure, a molecular mass of the additional gas is greater than a molecular mass of the deposited gas, and the additional gas does not react with the deposited gas.

15. The manufacturing method of the encapsulation layer according to claim 14, wherein the additional gas is one or more of a gas having a molecular mass greater than that of silane gas, argon gas, krypton gas, or radon gas.

16. The manufacturing method of the encapsulation layer according to claim 13, wherein the step of forming the adhesive layer on the first inorganic layer, wherein the surface of the adhesive layer away from the first inorganic layer has the microporous structure, comprises:
passing a deposited gas into a reaction chamber, wherein the deposited gas is deposited on the first inorganic layer to form a prefabricated adhesive layer; and
performing etching on a surface of the prefabricated adhesive layer using an etching gas to form the adhesive layer with the surface having the microporous structure.
